(19) United States
(12) Patent Application Publication
(10) Pub. No.: US 2007/0146022 A1
(43) Pub. Date: Jun. 28, 2007

(54) ANALOG FREQUENCY DIVIDER

(75) Inventor: Junji Inoue, Tokyo (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Kabushiki Kaisha Toyota Jidoshokki, Kariya-shi (JP)

(21) Appl. No.: 11/612,151

(22) Filed: Dec. 18, 2006

(30) Foreign Application Priority Data
Dec. 19, 2005 (JP) 2005-365298

(51) Int. Cl. H03K 23/00

(52) U.S. Cl. 327/115

(57) ABSTRACT

The parallel circuit of an inductor L1 and a resistor R1 is connected between a power supply voltage VDD and the drain of a MOS transistor TR1 as a load, and the parallel circuit of am inductor L2 and a resistor R2 is connected between a power supply voltage VDD and the drain of a MOS transistor TR2 as a load.

### CROSS REFERENCE TO RELATED APPLICATIONS

This application claims priority to Japanese Patent Application No. 2005-365298 Dec. 19, 2005.

### FIELD OF THE INVENTION

The present invention relates to an analog frequency divider used in an RF frequency band.

### BACKGROUND OF THE INVENTION

Conventionally, the circuit shown in FIG. 1 is used for an analog frequency divider. In the analog frequency divider 20 shown in FIG. 1, two stages of flip-flop circuits each composed of an amplifier for amplifying signals and a latch unit for maintaining the output state of the amplifier is connected.

The amplifier of the first stage flip-flop circuit comprises MOS transistors TR1, TR2 and TR5 and a current source 11 and its latch unit comprises MOS transistors TR3, TR4 and TR6 and a current source 12. The amplifier of the second stage flip-flop circuit comprises MOS transistors TR7, TR8 and TR11 and a current source 13 and its latch unit comprises MOS transistors TR9, TR10 and TR12 and a current source 14.

The analog frequency divider 20 outputs signals obtained by dividing an input signal RFIN+ and its inverted signal RFIN− by two as RFOUT+ and RFOUT−, respectively.

The conventional analog frequency divider 20 has a problem that the gain of the amplification circuit decreases in an RF frequency band and the frequency dividing operation is impossible since resistors are used as the load of MOS transistors TR1, TR2, TR7 and TR8. Therefore it is difficult to use it in an RF frequency band, such as a GHz band and the like. FIG. 8 of Patent reference 1 discloses that the series circuit of an inductor and a resistor is used as the load of the data reading unit of the flip-flop circuit. By using the series circuit of an inductor and a resistor, the operational frequency band of a frequency divider can be extended.

In the conventional analog frequency divider 20 shown in FIG. 1, it is necessary to increase current flowing through the MOS transistors in order to secure a specific or higher gain in an RF frequency band and to extend the operational frequency band of the frequency divider. As a result, power consumption increases.

In the invention disclosed by Patent document (page 3, lines 8-9) 1, the value of a resistor to be connected in series must be reduced in order to extend the operational frequency band of a frequency divider. However, if the resistance value is small, the resistance value varies widely, which greatly affects the Q value of the frequency divider. Specifically, the Q value may not decrease by the dispersion. Therefore, the operational frequency band of the frequency divider is restricted.

### SUMMARY OF THE INVENTION

It is an object of the present invention to provide an analog frequency divider whose operational frequency band is wide.

The analog frequency divider of the present invention comprises power supply voltage, first and second MOS transistors, first and second load each of which is made of the parallel circuit of an inductor and a resistor and which are connected between the drains of the first and second MOS transistors and the power supply voltage, a third MOS transistor whose drain is connected to the drain of the first MOS transistor and to whose gate is connected the output of the second MOS transistor, a fourth MOS transistor whose drain is connected to the drain of the second MOS transistor and to whose gate is connected the output of the first MOS transistor, a fifth MOS transistor whose drain is connected to the sources of the first and second MOS transistors and to whose gate is inputted an analog input signal P, a sixth MOS transistor whose drain is connected to the sources of the third and fourth MOS transistors and to whose gate is inputted the inverted signal N of the input signal P, a seventh MOS transistor whose gate is inputted the output of the first MOS transistor, a eighth MOS transistor whose gate is inputted the output of the second MOS transistor, third and fourth load which is made of the parallel circuit of an inductor and a resistor and which are connected between the drains of the seventh and eighth MOS transistors and the power supply voltage, a ninth MOS transistor whose drain is connected to the drain of the seventh MOS transistor and to whose gate is inputted the output of the eighth MOS transistor, a tenth MOS transistor whose drain is connected to the drain of the eighth MOS transistor and to whose gate is inputted an output of the seventh MOS transistor, an eleventh MOS transistor whose drain is connected to sources of the seventh and eighth MOS transistors and to whose gate is inputted the inverted signal N, a twelfth MOS transistor whose drain is connected to the sources of the ninth and eleventh MOS transistors and to whose gate is inputted the input signal P, and a current source which is connected between a sources of the fifth, sixth, eleventh and twelfth MOS transistor and the ground.

According to the present invention, the operational frequency band of a frequency divider can be extended by using the parallel circuit of an inductor and a resistor as the load of the first, second, seventh and eighth MOS transistors. Since the load is made of the parallel circuit of an inductor and a resistor, the resistance value can be increased compared with the series circuit of an inductor and a resistor. By increasing the resistance value, the Q value of the analog frequency divider can be prevented from varying due to the dispersion of the resistance value. More particularly, if an analog frequency divider is formed on a semiconductor device, the device area of a resistor needed to realize a necessary resistance value can be reduced since the resistance value can be fairly easily formed on the semiconductor device.

In the analog frequency divider of the present invention, first and second capacitors are connected between the output of the ninth and tenth MOS transistors and the ground, respectively.

With such a configuration, for example, even when an inductance is formed on a semiconductor and the inductor values varies widely, the Q value of the circuit can be designed value by setting the capacitance value of the capacitor to an appropriate value corresponding to the value of an inductor formed on the semiconductor device.

### BRIEF DESCRIPTION OF THE DRAWINGS

FIG. 1 shows the circuit diagram of the conventional analog frequency divider;

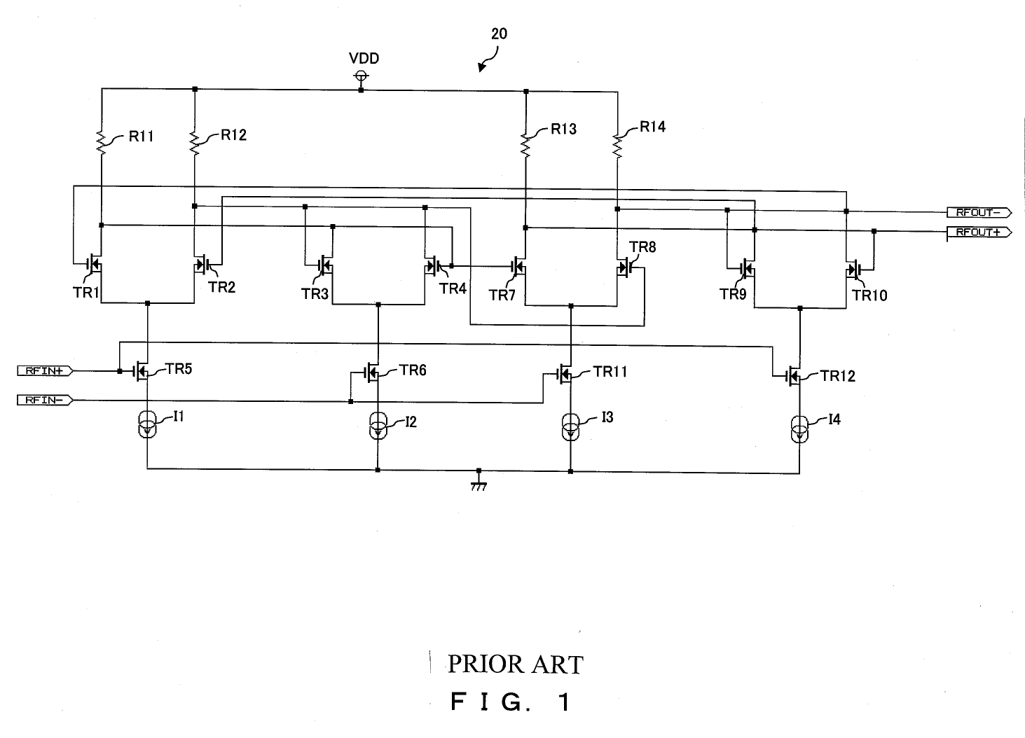

FIG. 2 shows the circuit diagram of the analog frequency divider of the preferred embodiment;

FIG. 3 is the operational chart of the analog frequency divider (No. 1);

FIG. 4 is the operational chart of the analog frequency divider (No. 2);

FIG. 5 is the operational chart of the analog frequency divider (No. 3).

### DETAILED DESCRIPTION OF ILLUSTRATIVE EMBODIMENTS

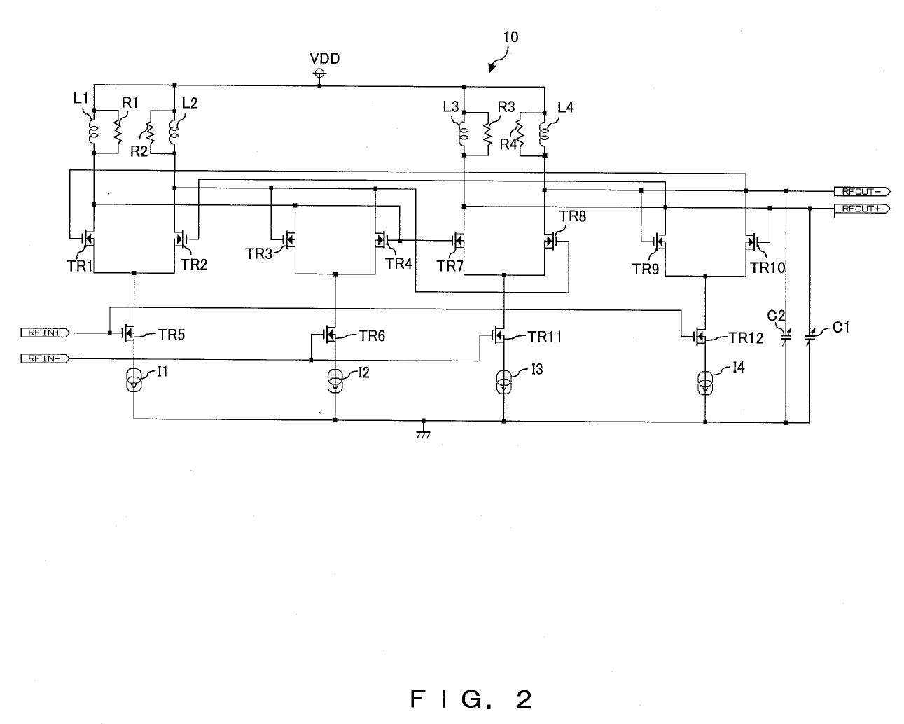

The preferred embodiments are described below with reference to the drawings. FIG. 2 shows the circuit diagram of the analog frequency divider of the preferred embodiment. This analog frequency divider is formed, for example, on a semiconductor device manufactured in a MOS process.

An analog frequency divider 10 is used, for example, in an RF frequency band of 5 GHz or more. To the analog frequency divider, an RFIN+ signal (corresponding to an input signal P) and its inverted signal RFIN− (corresponding to an inverted signal N) are inputted. The input signal RFIN+ and the inverted signal RFIN− are, for example, the output signal of a voltage controlled oscillator (VCO) and a signal obtained by inverting the output signal.

In the analog frequency divider 10 shown in FIG. 2, an amplifier for amplifying input signals RFIN+ and RFIN− and a latch unit are connected in two stages, and has a function to divide the input signals RFIN+ and RFIN− respectively in half in frequencies.

n-channel MOS transistors (hereinafter called a “MOS transistor”) TR1 and TR2, a MOS transistor TR5 and a current source 11 constitute the first stage amplifier unit.

Between power supply voltage VDD and the drain of the MOS transistor TR1, the parallel circuit of an inductor L1 and a resistor R1 is connected as a load, and between the power supply voltage VDD and the drain of the MOS transistor TR2, the parallel circuit of an inductor L2 and a resistor R2 is connected as a load.

To the gate of the MOS transistor TR5, the input signal RFIN+ is inputted, and the drain of the MOS transistor TR5 is commonly connected to the sources of the MOS transistors TR1 and TR2. Between the source of the MOS transistor TR5 and the ground, the current source 11 is connected.

MOS transistors TR3 and TR4, a MOS transistor TR6 and a current source 12 constitute the first stage latch unit for maintaining the output state of the MOS transistors TR1 and TR2.

The drain of the MOS transistor TR3 and the gate of the MOS transistor TR4 are connected to the drain of the MOS transistor TR1, and the gate of the MOS transistor TR3 and the drain of the MOS transistor TR4 are connected to the drain of the MOS transistor TR2.

To the gate of a MOS transistor 6, the inverted signal RFIN− is inputted, and the drain of the MOS transistor 6 is commonly connected to the sources of the MOS transistors TR3 and TR4. Between the source of the MOS transistor TR6 and the ground, a current source 12 is connected.

MOS transistors TR7 and TR8, a MOS transistor 11 and a current source 13 constitute the second stage amplification unit.

Between the power supply voltage VDD and the drain of the MOS transistor TR7, the parallel circuit of an inductor L3 and a resistor R3 is connected as a load, and between the power supply voltage VDD and the drain of a MOS transistor TR8, the parallel circuit of an inductor L4 and a resistor R4 is connected as a load.

The gate of the MOS transistor TR7 is connected to the drain of the MOS transistor TR1, and the gate of the MOS transistor TR8 is connected to the drain of the MOS transistor TR2.

To the gate of the MOS transistor TR11, the inverted signal REIN− is inputted, and the drain of the MOS transistor TR11 is commonly connected to the sources of the MOS transistor TR7 and TR8. Between the source of this MOS transistor TR11 and the ground, the current source 13 is connected.

MOS transistors TR9 and TR10, a MOS transistor TR12 and a current source 14 constitute the second stage latch unit for maintaining the output state of the MOS transistors TR7 and TR8.

The drain of the MOS transistor TR9 and the gate of the MOS transistor TR10 are connected to the drain of the MOS transistor TR7 and the gate of the MOS transistor TR2. The gate of the MOS transistor TR9 and the drain of the MOS transistor TR1 are connected to the drain of the MOS transistor TR8 and the gate of the MOS transistor TR1.

To the gate of the MOS transistor TR12, the input signal RFIN+ is inputted and, the drain of the MOS transistor TR12 is commonly connected to the sources of the MOS transistors TR9 and TR10. Between the source of the MOS transistor TR12 and the ground, the current source 14 is connected.

A capacitor C1 is connected between the drain of the MOS transistor TR9, which is its output, and the ground. A capacitor C2 is connected between the drain of the MOS transistor TR10 and the ground.

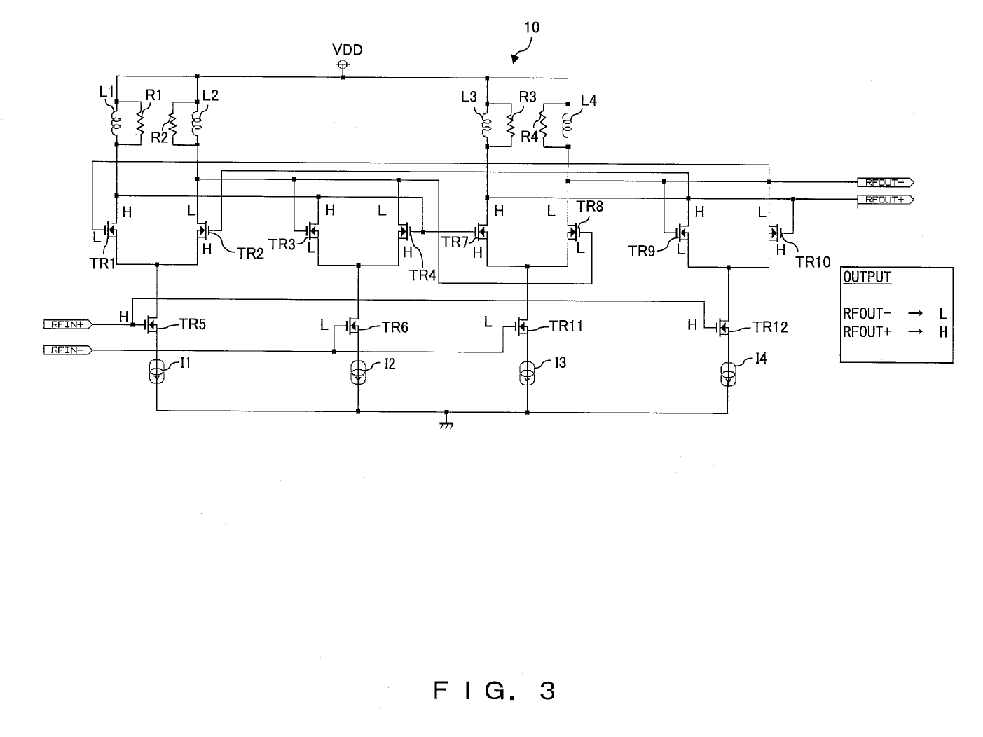

The operation of the analog frequency divider 10 shown in FIG. 2 is described below with reference to the operational charts of FIGS. 3-5.

The operation of the frequency divider 10 in the case where the input signal RFIN+ change to a high level, and the inverted signal RFIN− change to a low level when the outputs of the MOS transistors TR7 and TR9 are at a high level (beyond the threshold voltage of the gate) and the outputs of the MOS transistors TR8 and TR10 are at a low level (below the threshold voltage of the gate) is described with reference to FIG. 3. H and L characters in the neighborhood of the gate and drain of the MOS transistor shown in FIGS. 3-5 show voltage levels.

When the input signal RFIN+ is at a high level, the MOS transistor TR5 is switched on. In this case, since the MOS transistor TR1 is switched off since its gate voltage is at a low level and the drain voltage (output voltage) is at a high level. In this case, since the gate voltage of the MOS transistor TR2 is at a high level, the MOS transistor TR2 is switched off and the drain voltage is at a low level.

Since the drain voltage of the MOS transistor TR1 is at a high level, the gate voltage of the MOS transistor TR4 is also at a high level, and the MOS transistor TR4 is switched on. Since the gate voltage of the MOS transistor TR2 is at a low level, the gate voltage of the MOS transistor TR3 is at a low level and the MOS transistor TR3 is switched off.

To the gate of the MOS transistor TR7, the same high level voltage as the gate of the MOS transistor TR4 is given and to the gate of the MOS transistor TR8, the same low level voltage as the gate of the MOS transistor TR3 is given. However, in this case, since the inverted signal RFIN− is at a low level and the MOS transistor TR11 is switched off, the drain voltages of the MOS transistors TR7 and TR8 are determined by the drain voltages of the MOS transistors TR9 and TR10.

When the input signal RFIN+ is at a high level, the MOS transistor TR12 is switched on. In this case, since the gate voltages of the MOS transistors TR1 is at low level, and TR2 is at high level the drain voltage (output signal RFOUT+) of the MOS transistor TR9 is at high level, and the drain voltage (inverted output signal RFOUT−) is at low level.

Therefore, the output signal RFOUT+0 is at high level, and inverted output signal RFOUT− is at low level.

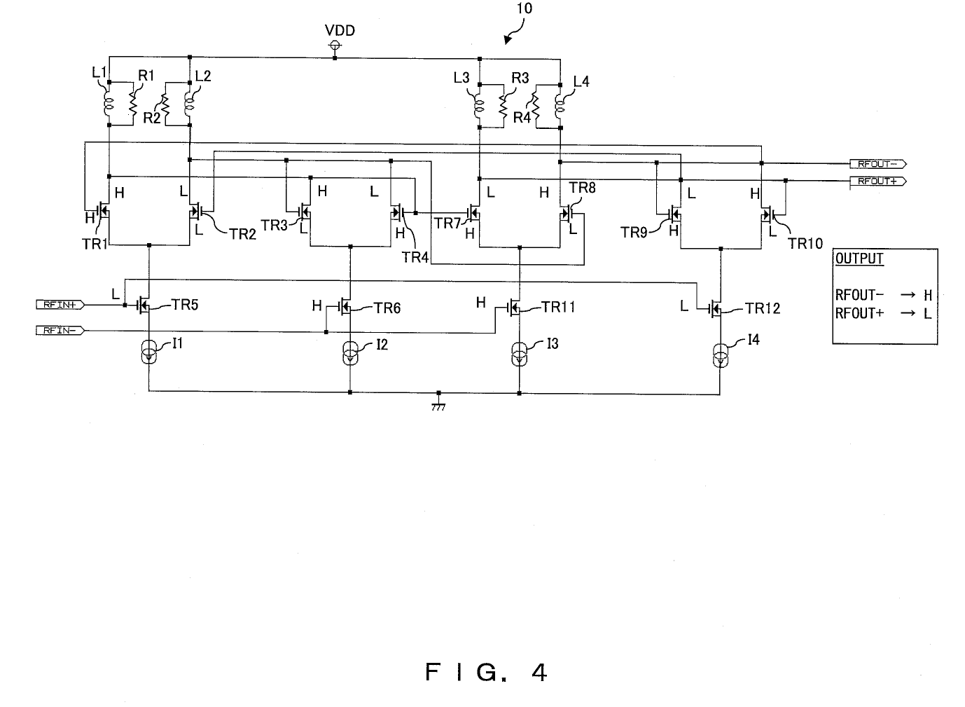

Next, the operation of the frequency divider 10 in the case where the input signal RFIN+ changes to a low level from the state shown in FIG. 3 is described with reference to FIG. 4.

When the input signal RFIN+ changes from a high level to a low level, the MOS transistor TR12 is switched off. In this case, the output voltages of the MOS transistors TR9 and TR10 are determined by the respective state of the MOS transistors TR7 and TR8.

When the inverted signal RFIN− changes from a low level to a high level, the MOS transistor TR11 is switched on. In this case, since the gate voltages of the MOS transistors TR7 is at high level and TR8 is at low level, the MOS transistors TR7 is switched on, and TR8 is switched off.

Therefore, the drain voltages of the MOS transistors TR7 is at low level, and TR8 is at high level. Therefore, the output signal RFOUT+ changes from a high level to a low level.

Even when the output signal RFOUT+ change to low level, and the output inverted signal RFIN− change to high level, and the gate voltages of the MOS transistors TR2 change to low level, and TR1 change to high level, in this case, the MOS transistor TR5 is switched off. Therefore, the outputs of the MOS transistors TR2 and TR1, specifically, the drain voltages maintain the same state.

Therefore, the output signal RFOUT+ is at low, and the inverted output signal RFOUT− is at high level.

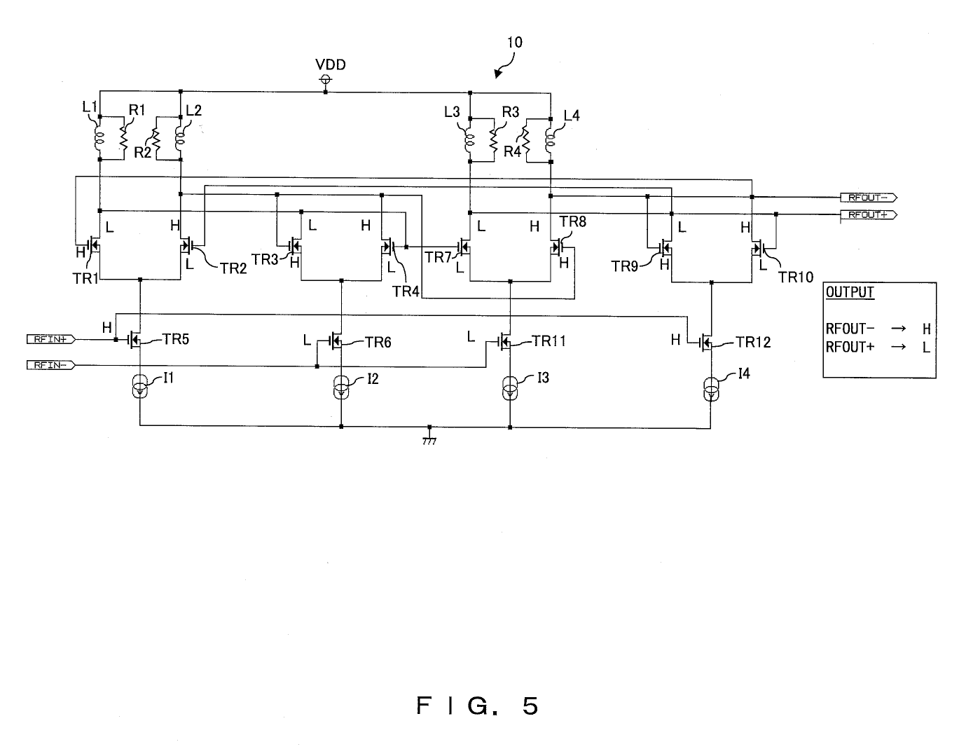

Next, the operation of the frequency divider 10 in the case where the input signal RFIN+ changes to a high level from the state shown in FIG. 4 is described with reference to FIG. 5.

When the input signal level RFIN+ changes from a low level to a high level, the MOS transistor TR5 is switched on. In this case, since the gate voltages of the MOS transistors TR1 is at high, and TR2 is at low level, the MOS transistors TR1 is switched on, and TR2 is switched off. Therefore, the drain voltages of the MOS transistors TR1 is at low, and TR2 is at high level. Accordingly, the drain voltages of the MOS transistors TR3 change to low, and TR4 change to high level.

When the input signal RFIN+ changes to a high level, the MOS transistor TR12 is switched on. IN this case, since the gate voltage of the MOS transistor TR9 is at a high level, the MOS transistor TR9 is switched on and the drain voltage of the MOS transistor TR9 maintains the low level. Since the gate voltage of the MOS transistor TR10 is at a low level, the MOS transistor TR10 is switched off and the drain voltage of the MOS transistor TR10 maintains the high level.

Therefore, the output signal RFOUT+ maintains the immediately previous low level and the inverted output signal RFOUT− maintains the high level.

Next, the operation of the frequency divider 10 in the case where the input signal RFIN+ changes to a low level from the state shown in FIG. 5 is described.

When the input signal RFIN+ changes from a high level to a low level (the inverted signal RFIN− changes from a low level to a high level), the MOS transistors TR6 and TR11 are switched on. In this case, since the gate voltages of the MOS transistors TR7 and TR8 are at low and high levels, the MOS transistors TR7 is switched off, and TR8 is switched on. Therefore, the drain voltages of the MOS transistors TR7 change to high, and TR8 change to low level.

In this case, since the MOS transistor TR12 is switched off, the outputs of the MOS transistors TR9 and TR10 are determined by the drain voltages of the MOS transistors TR7 and TR8.

Therefore, the output signal RFOUT+ is at high, and the inverted output signal RFOUT− is at low level.

Specifically, when the inverted signal RFIN− changes from a low level to a high level, the inverted output signal RFOUT− changes either from a high level to a low level or from a low level to a high level. When the input signal RFIN+ changes from a high level to a low level, the output signal RFOUT+ changes either from a high level to a low level or from a low level to a high level.

By repeating the above-described operation, an output signal RFOUT+ with the double cycle of the input signal RFIN+ and its inverted output signal RFOUT− can be generated.

According to the analog frequency divider 10 of the above-described preferred embodiment, the values (for example, several hundredΩ-several k Ω) of the resistors R1-R4 can be increased compared with the resistance value (for example, 0-several ten Ω) of the series circuit of an inductor L and a resistor R, by using the parallel circuit of an inductor L1 and a resistor R1 and the parallel circuit of an inductor L2 and a resistor R2 as the loads of the MOS transistors TR1 and TR2. Furthermore using the parallel circuit of an inductor L3 and a resistor R3 and the parallel circuit of inductor L4 and a resistor R4 as the loads of the MOS transistors TR7 and TR8. Thus, when forming a frequency divider on a semiconductor device, the dispersion of the Q value of the frequency divider due to the dispersion of the resistance value can be reduced.

Since the resistance value can be set to approximately several hundred Ω-several k Ω by using the parallel circuit of an inductor and a resistor, a resistor which can be easily formed on a semiconductor device can be used. Furthermore, since the resistance value can be increased compared with the series circuit of an inductor and a resistor, there is no need to reduce the resistance value by connecting a plurality of resistors formed on the semiconductor device in parallel. Thereby reducing the device area of the resistor when forming a resistor with a desired value.

Even if the value of the inductor formed on the semiconductor device varies, the value of the capacitor can be determined in such a way as to be a desired resonant frequency, by adjusting the capacitance value of the capacitor in accordance with to the actual inductance value. Thus, when designing, the design capacitance value of the capacitor can be matched with the actual inductance value of the semiconductor device. Although in FIG. 2, the capacitors C1 and C2 are marked with variable capacitor symbols, this indicates that while designing, the capacitance value of the capacitor can be adjusted according to the actual capacitance value, and the capacity fixed in the final circuit.

According to the above-described invention, an analog frequency divider with a wide operational frequency band can be provided by using the parallel circuit of an inductor and a resistor as the load of the MOS transistor.

The present invention is not limited to the above-described preferred embodiments and can also be configured as follows.

(1) Although in the above-described preferred embodiments, the frequency divider 10 is composed of n-channel MOS transistors, it can also be composed of p-channel MOS transitors or bi-polar transistors. When it is composed of p-channel MOS transistors, for example, the current source 11 is connected to the power supply side, a p-channel MOS transitors TR5 connected to the current source 11, p-channel MOS transistors TR1 and TR2 are connected to the p-channel MOS transistor TR5 and the parallel circuit of an inductor and a resistor is connected between the drains of the p-channel MOS transistors TR1 and TR2 and the ground.

(2) The number of current sources used for the frequency divider 10 is not limited to four, and the number can be reduced to 1-3 by grouping a plurality of current sources.

(3) The current source is not limited to the current mirror circuit and can be a circuit which provides its gate with bias voltage.

What is claimed is:

1. An analog frequency divider, comprising:
a power supply voltage;
first and second MOS transistors;
first and second loads each of which is made of a parallel circuit of an inductor and a resistor and which are connected between drains of the first and second MOS transistors and the power supply voltage;
a third MOS transistor whose drain is connected to the drain of the first MOS transistor and to whose gate is connected an output of the second MOS transistor;
a fourth MOS transistor whose drain is connected to the drain of the second MOS transistor and to whose gate is connected an output of the first MOS transistor;
a fifth MOS transistor whose drain is connected to sources of the first and second MOS transistors and to whose gate is inputted an analog input signal P;
a sixth MOS transistor whose drain is connected to sources of the third and fourth MOS transistors and to whose gate is inputted an inverted signal N of the input signal P;
a seventh MOS transistor whose gate is inputted an output of the first MOS transistor;
an eighth MOS transistor whose gate is inputted an output of the second MOS transistor;
third and fourth loads each of which is made of a parallel circuit of an inductor and a resistor and which are connected between drains of the seventh and eighth MOS transistors and the power supply voltage;
a ninth MOS transistor whose drain is connected to the drain of the seventh MOS transistor and to whose gate is inputted an output of the eighth MOS transistor;
a tenth MOS transistor whose drain is connected to the drain of the eighth MOS transistor and to whose gate is inputted an output of the seventh MOS transistor;
an eleventh MOS transistor whose drain is connected to sources of the seventh and eighth MOS transistors and to whose gate is inputted the inverted signal N;
a twelfth MOS transistor whose drain is connected to sources of the ninth and eleventh MOS transistors and to whose gate is inputted the input signal P; and
a current source which is connected between a source of the fifth, sixth, eleventh and twelfth MOS transistor and the ground.

2. The analog frequency divider according to claim 1, wherein
first capacitor is connected between a drain of the ninth MOS transistor and the ground, and second capacitor is connected between a drain of the tenth MOS transistor and the ground.

3. An analog frequency divider, comprising:
a power supply voltage;
first and second bi-polar transistors;
first and second loads each of which is made of a parallel circuit of an inductor and a resistor and which are connected between collectors of the first and second bi-polar transistors and the power supply voltage;
a third bi-polar transistor whose collector is connected to the collector of the first bi-polar transistor and to whose base is connected an output of the second bi-polar transistor;
a fourth bi-polar transistor whose collector is connected to the collector of the second bi-polar transistor and to whose base is connected an output of the first bi-polar transistor;
a fifth bi-polar transistor whose collector is connected to emitters of the first and second bi-polar transistors and to whose base is inputted an analog input signal P;
a sixth bi-polar transistor whose collector is connected to emitters of the third and fourth bi-polar transistors and to whose base is inputted an inverted signal N of the input signal P;
a seventh bi-polar transistor whose base is inputted an output of the first bi-polar transistor;
an eighth bi-polar transistor whose base is inputted an output of the second bi-polar transistor;
third and fourth loads each of which is made of a parallel circuit of an inductor and a resistor and which are connected between collectors of the seventh and eighth bi-polar transistors and the power supply voltage;
a ninth bi-polar transistor whose collector is connected to the collector of the seventh bi-polar transistor and to whose base is inputted an output of the eighth bi-polar transistor;
a tenth bi-polar transistor whose collector is connected to the collector of the eighth bi-polar transistor and to whose base is inputted an output of the seventh bi-polar transistor;
an eleventh bi-polar transistor whose collector is connected to emitters of the seventh and eighth bi-polar transistors and to whose base is inputted the inverted signal N;
a twelfth bi-polar transistor whose collector is connected to emitters of the ninth and eleventh bi-polar transistors and to whose base is inputted the input signal P; and
a current source which is connected between a source of the fifth, sixth, eleventh and twelfth bi-polar transistor and the ground.

4. The analog frequency divider according to claim 3, wherein
first capacitor is connected between a collector of the ninth bi-polar transistor and the ground and second capacitor is connected between a collector of the tenth bi-polar transistor and the ground.

5. An analog frequency divider, comprising:
a power supply voltage;
first and second MOS transistors;
first and second loads each of which is made of a parallel circuit of an inductor and a resistor and which are connected between drains of the first and second MOS transistors and the power supply voltage;
a third MOS transistor whose drain is connected to the drain of the first MOS transistor and to whose gate is connected an output of the second MOS transistor;
a fourth MOS transistor whose drain is connected to the drain of the second MOS transistor and to whose gate is connected an output of the first MOS transistor;
a fifth MOS transistor whose drain is connected to sources of the first and second MOS transistors and to whose gate is inputted an analog input signal P;
a sixth MOS transistor whose drain is connected to sources of the third and fourth MOS transistors and to whose gate is inputted an inverted signal N of the input signal P;
a seventh MOS transistor whose gate is inputted an output of the first MOS transistor;
an eighth MOS transistor whose gate is inputted an output of the second MOS transistor;
third and fourth loads each of which is made of a parallel circuit of an inductor and a resistor and which are connected between drains of the seventh and eighth MOS transistors and the power supply voltage;
a ninth MOS transistor whose drain is connected to the drain of the seventh MOS transistor and to whose gate is inputted an output of the eighth MOS transistor;
a tenth MOS transistor whose drain is connected to the drain of the eighth MOS transistor and to whose gate is inputted an output of the seventh MOS transistor;
an eleventh MOS transistor whose drain is connected to sources of the seventh and eighth MOS transistors and to whose gate is inputted the inverted signal N;
a twelfth MOS transistor whose drain is connected to sources of the ninth and eleventh MOS transistors and to whose gate is inputted the input signal P; and
a current source which is connected between a source of the fifth, sixth, eleventh and twelfth MOS transistor and the power supply voltage.

6. The analog frequency divider according to claim 5, wherein
first capacitor is connected between a drain of the ninth MOS transistor and the ground, and second capacitor is connected between a drain of the tenth MOS transistor an the ground.

7. An analog frequency divider, comprising:
a power supply voltage;
first and second bi-polar transistors;
first and second loads each of which is made of a parallel circuit of an inductor and a resistor and which are connected between collectors of the first and second bi-polar transistors and the power supply voltage;
a third bi-polar transistor whose collector is connected to the collector of the first bi-polar transistor and to whose base is connected an output of the second bi-polar transistor;
a fourth bi-polar transistor whose collector is connected to the collector of the second bi-polar transistor and to whose base is connected an output of the first bi-polar transistor;
a fifth bi-polar transistor whose collector is connected to emitters of the first and second bi-polar transistors and to whose base is inputted an analog input signal P;
a sixth bi-polar transistor whose collector is connected to emitters of the third and fourth bi-polar transistors and to whose base is inputted an inverted signal N of the input signal P;
a seventh bi-polar transistor whose base is inputted an output of the first bi-polar transistor;
an eighth bi-polar transistor whose base is inputted an output of the second bi-polar transistor;
third and fourth loads each of which is made of a parallel circuit of an inductor and a resistor and which are connected between collectors of the seventh and eighth bi-polar transistors and the power supply voltage;
a ninth bi-polar transistor whose collector is connected to the collector of the seventh bi-polar transistor and to whose base is inputted an output of the eighth bi-polar transistor;
a tenth bi-polar transistor whose collector is connected to the collector of the eighth bi-polar transistor and to whose base is inputted an output of the seventh bi-polar transistor;
an eleventh bi-polar transistor whose collector is connected to emitters of the seventh and eighth bi-polar transistors and to whose base is inputted the inverted signal N;
a twelfth bi-polar transistor whose collector is connected to emitters of the ninth and eleventh bi-polar transistors and to whose base is inputted the input signal P; and
a current source which is connected between a source of the fifth, sixth, eleventh and twelfth bi-polar transistor and the power supply voltage.

8. The analog frequency divider according to claim 7, wherein first capacitor is connected between a collector of the ninth bi-polar transistor and the ground, and second capacitor is connected between a collector of the ninth bi-polar transistor and the ground.
